(19) United States
(12) Patent Application Publication
(10) Pub. No.: US 2021/0013437 A1
(43) Pub. Date: Jan. 14, 2021

(54) QUANTUM DOT LIGHT-EMITTING DIODE

(71) Applicant: TCL TECHNOLOGY GROUP CORPORATION, Huizhou (CN)

(72) Inventors: Liang SU, Huizhou (CN); Xiangwei XIE, Huizhou (CN)

(21) Appl. No.: 16/955,705

(22) PCT Filed: Sep. 24, 2019
(86) PCT No.: PCT/CN2019/107552

§ 371 Date: Jun. 18, 2020

(30) Foreign Application Priority Data
Sep. 29, 2018 (CN) 201811150182.5
Sep. 29, 2018 (CN) 201811150184.4

(51) Int. Cl. H01L 51/50; H01L 51/52

(52) U.S. Cl. CPC H01L 51/502; H01L 51/5221; H01L 51/5206; H01L 51/5056

(57) ABSTRACT

Disclosed is a quantum dot light-emitting diode, comprising a hole function layer arranged between an anode and a quantum dot light-emitting layer, wherein the hole function layer comprises a hole transport layer and a hole buffer layer; the hole transport layer is arranged close to the anode; the hole buffer layer is arranged close to the quantum dot light-emitting layer and comprises a first hole buffer sub-layer arranged affixed to the hole transport layer; and the material of the first hole buffer sub-layer is a first hole buffer material or a combined material composed of the first hole buffer material and a first hole transport material. The conductance of the first hole buffer material is less than 1×10⁻⁸ Sm⁻¹, or, the hole mobility of the first hole buffer material is less than 1×10⁻⁶ cm²V⁻¹s⁻¹.

### CROSS-REFERENCES TO RELATED APPLICATIONS

This application is a national stage application of PCT Patent Application No. PCT/CN2019/107552, filed on Sep. 24, 2019, which claims priority to Chinese Patent Application No. 201811150182.5 & 201811150184.4, filed on Sep. 29, 2018, the content of all of which is incorporated herein by reference.

### FIELD OF THE INVENTION

The present disclosure relates to the field of light-emitting diode, and more particularly, to a quantum dot light-emitting diode.

### BACKGROUND

A quantum dot has a plurality of unique optical properties including: a continuously adjustable emission wavelength according to sizes and compositions, a narrow emission spectrum, high fluorescence efficiency, and a good stability, which has made a quantum dot based electroluminescent diode (QLED, Quantum dot based Light-Emitting Diode) be widely concerned and studied. In addition, a QLED display further has a plurality of advantages that an LCD may not achieve, including a large viewing angle, a high contrast, a fast response speed, flexibility and more, thus it is expected to become a next generation display technology. After over 20 years of a continuous research and development, a performance (a luminous efficiency, a service life) of the QLED has been greatly improved; however there is still a considerable distance from commercialization, especially for a blue light LED.

Currently, there is a big bottleneck in developing the QLED, that is, there is no suitable hole transport material. Because currently a HOMO level of the hole transport material does not match a valence band maximum (VBM) of the quantum dot, that results in a hole injection barrier existing between a hole transport layer and a quantum dot layer relatively large; as a contrast, an electron injection barrier from an electron transport layer to the quantum dot layer is much smaller or even zero, which causes an electron to easily move into the quantum dot, while a hole accumulates more on an interface between the hole transport layer and a quantum dot light-emitting layer. A plurality of holes accumulated at the interface forms a spatial charge zone, and generates a spatial electric field. On one hand, an existence of the spatial electric field may further hinder the holes from continuously moving to the quantum dots, resulting in a more unbalance for a charge transfer; on other hand, the spatial electric field may cause an exciton separation in the quantum dot, resulting in a quantum dot fluorescence quenching, both may reduce a performance of the QLED. Besides, the holes accumulating at a very narrow interface may also raise a high requirement on an electricity resistance of the hole transport material, which often causes a brightness and an efficiency of the QLED decline rapidly, due to a low electricity resistance of the hole transport material.

Therefore, the current technology needs to be improved and developed.

### BRIEF SUMMARY OF THE DISCLOSURE

According to the above described defects, the purpose of a disclosure is providing a quantum dot light-emitting diode, in order to solve a problem in the prior art that, a quantum dot light-emitting diode in the prior art, is easy to generate a spatial electric field due to a plurality of holes accumulating at an interface between a hole transport layer and a quantum dot layer, causing a relatively low light-emitting efficiency of the quantum dot light-emitting diode

A technical solution of the present disclosure to solve the technical problems is as follows:

a quantum dot light-emitting diode, comprising, arranged in a stack: an anode, a cathode, a quantum dot light-emitting layer arranged between the anode and the cathode, and a hole function layer arranged between the anode and the quantum dot light-emitting layer; the hole function layer comprises a hole transport layer and a hole buffer layer, the hole transport layer is arranged close to the anode, the hole buffer layer is arranged close to the quantum dot light-emitting layer, wherein the hole buffer layer comprises a first hole buffer sub-layer arranged and affixed to the hole transport layer, and a material of the first hole buffer sub-layer is a first hole buffer material or a mixed material composed of a first hole buffer material and a fourth hole transport material, wherein an electrical conductivity of the first hole buffer material is less than 1×10⁻⁸ Sm⁻¹.

A quantum dot light-emitting diode, comprising, arranged in a stack: an anode, a cathode, a quantum dot light-emitting layer arranged between the anode and the cathode, and a hole function layer arranged between the anode and the quantum dot light-emitting layer; the hole function layer comprises a hole transport layer and a hole buffer layer, the hole transport layer is arranged close to the anode, the hole buffer layer is arranged close to the quantum dot light-emitting layer, wherein the hole buffer layer comprises a first hole buffer sub-layer arranged and affixed to the hole transport layer, and a material of the first hole buffer sub-layer is a first hole buffer material or a mixed material composed of a first hole buffer material and a fourth hole transport material, wherein a hole mobility of the first hole buffer material is less than 1×10⁻⁶ cm²V⁻¹s⁻¹.

Benefits: In the present disclosure, the hole buffer layer may hinder the holes from transmitting to the quantum dot light-emitting layer, making a part of the holes be scattered on the interface between the hole transport layer and the hole buffer layer, so as to reduce an accumulative density of the holes on an interface between the hole transport layer and the quantum dot light-emitting layer, broaden a hole accumulation zone, and make the hole accumulation zone separate from an exciton recombination zone, reduce a fluorescence quenching of a quantum dot caused by a spatial electric field, which may not only improve an electricity resistance of the hole transport layer, but also improve a luminous efficiency, a stability and a service life of the QLED.

### BRIEF DESCRIPTION OF THE DRAWINGS

FIG. 1 illustrates a schematic diagram on a quantum dot light-emitting diode having a first structure consistent with the disclosed embodiments.

FIG. 2 illustrates a schematic diagram on a hole accumulation zone and an exciton recombination zone of a quantum dot light-emitting diode in the prior art.

FIG. 3 illustrates a schematic diagram on a hole accumulation zone and an exciton recombination zone of a quantum dot light-emitting diode in the FIG. 1 of the disclosed embodiments.

FIG. 4 illustrates a schematic diagram on a quantum dot light-emitting diode having a second structure consistent with the disclosed embodiments.

FIG. 5 illustrates a schematic diagram on a hole accumulation zone and an exciton recombination zone of a quantum dot light-emitting diode in the FIG. 4 of the disclosed embodiments.

FIG. 6 illustrates a schematic diagram on a quantum dot light-emitting diode having a third structure consistent with the disclosed embodiments.

FIG. 7 illustrates a schematic diagram on a hole accumulation zone and an exciton recombination zone of a quantum dot light-emitting diode in the FIG. 6 of the disclosed embodiments.

FIG. 8 illustrates a schematic diagram on a quantum dot light-emitting diode having a fourth structure consistent with the disclosed embodiments.

FIG. 9 illustrates a schematic diagram on a hole accumulation zone and an exciton recombination zone of a quantum dot light-emitting diode in the FIG. 8 of the disclosed embodiments.

FIG. 10 illustrates a schematic diagram on a quantum dot light-emitting diode having a fifth structure consistent with the disclosed embodiments.

FIG. 11 illustrates a schematic diagram on a hole accumulation zone and an exciton recombination zone of a quantum dot light-emitting diode in the FIG. 10 of the disclosed embodiments.

FIG. 12 illustrates a schematic diagram on a quantum dot light-emitting diode having a sixth structure consistent with the disclosed embodiments.

FIG. 13 illustrates a schematic diagram on a quantum dot light-emitting diode having a seventh structure consistent with the disclosed embodiments.

FIG. 14 illustrates a schematic diagram on a quantum dot light-emitting diode having an eighth structure consistent with the disclosed embodiments.

FIG. 15 illustrates a current density-voltage (J-V) curve of a QLED provided in the embodiments 5-9 of the disclosed embodiments.

FIG. 16 illustrates a current luminance-voltage (L-V) curve of a QLED provided in the embodiments 5-9 of the disclosed embodiments.

FIG. 17 illustrates a current efficiency-current density (CE-J) curve of a QLED provided in the embodiments 5-9 of the disclosed embodiments.

FIG. 18 illustrates a service life curve of a QLED provided in the embodiments 5-9 of the disclosed embodiments.

### DETAILED DESCRIPTION OF EMBODIMENTS

The present disclosure provides a quantum dot light-emitting diode, in order to make the purpose, technical solution and the advantages of the present disclosure clearer and more explicit, further detailed descriptions of the present disclosure are stated here, referencing to the attached drawings and some preferred embodiments of the present disclosure. It should be understood that the detailed embodiments of the disclosure described here are used to explain the present disclosure only, instead of limiting the present disclosure.

A quantum dot light-emitting diode (QLED) has a plurality of forms, and the quantum dot light-emitting diode may be divided into a cis structure and a trans structure. A quantum dot light-emitting diode having a trans structure may comprise, stacked from bottom up, a substrate, a cathode, a quantum dot light-emitting layer, a hole function layer and an anode. While in a plurality of implementations of the present disclosure, it will be introduced by mainly taking a quantum dot light-emitting diode having a cis structure as a plurality of embodiments. Further, the quantum dot light-emitting diode comprises, stacked from bottom up, a substrate, an anode, a hole function layer, a quantum dot light-emitting layer, and a cathode, wherein the hole function layer comprises a hole transport layer and a hole buffer layer, the hole transport layer is arranged close to the anode, while the hole buffer layer is arranged close to the quantum dot light-emitting layer; the hole buffer layer comprises a first hole buffer sub-layer arranged and affixed to the hole transport layer, a material of the first hole buffer sub-layer is a first hole buffer material or a mixed material composed of a fourth hole buffer material and a first hole transport material, wherein an electrical conductivity of the first hole buffer material is less than 1×10⁻⁸ Sm⁻¹.

In the present embodiment, a hole function layer is arranged between the anode and the quantum dot light-emitting layer, and the hole function layer comprises a hole transport layer and a hole buffer layer. By arranging the hole buffer layer, it is able to improve not only an electricity resistance of the hole transport layer, but also a luminous efficiency, a stability and a service life of the QLED. A mechanism for achieving a plurality of effects described above is further as follows:

since the hole buffer layer in the embodiment comprises a first hole buffer sub-layer arranged and affixed to the hole transport layer, when a material of the first hole buffer sub-layer is a first hole buffer material, and an electrical conductivity of the first hole buffer material is less than 1×10⁻⁸ Sm⁻¹, the first hole buffer sub-layer may make a plurality of holes originally all accumulated on an interface between the hole transport layer and the quantum dot light-emitting layer currently accumulate on an interface between the hole transport layer and the first hole buffer sub-layer, so as to separate the hole accumulation zone from the quantum dot exciton combination zone, which reduces an adverse effect of the spatial electric field to the exciton separation and the fluorescence quenching of the quantum dot, and improves the luminous efficiency, the stability and the service life of the QLED.

In the present embodiment, when the material of the first hole buffer sub-layer is a mixed material composed of a first hole buffer material and a fourth hole transport material, and an electrical conductivity of the first hole buffer material is less than 1×10⁻⁸ Sm⁻¹, the fourth hole transport material in the first hole buffer sub-layer may act as a channel for holes transport, while the first hole buffer material acts as a barrier for the holes transport, which may make all the holes originally accumulated on the interface between the hole transport layer and the quantum dot light-emitting layer get partially diffused in the first hole buffer sub-layer, thus achieving a purpose of widening the hole accumulation zone, while a widened hole accumulation zone may bring a plurality of following benefits: on one hand, the widened hole accumulation zone may reduce a requirement on the electricity resistance of the hole transport material, that is, the widened hole accumulation zone may reduce a density of the charges accumulated in per unit volume of the hole transport layer, thus the electricity resistance of the hole transport layer is improved in an alternative way, which helps to improve stability and a service life of the QLED; on another hand, a widened hole accumulation zone may reduce an electric field strength close to the interface of the quantum dot light-emitting layer, which helps to reduce an exciton separation caused by the electric field and reduce a quantum dot fluorescence quenching, thereby helping to improve the luminous efficiency and the service life of the QLED.

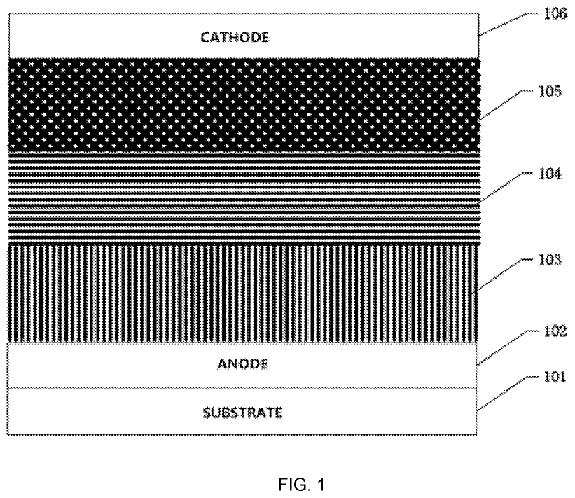

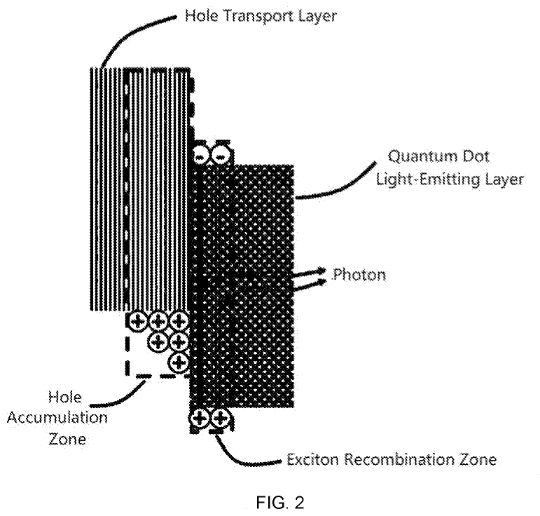

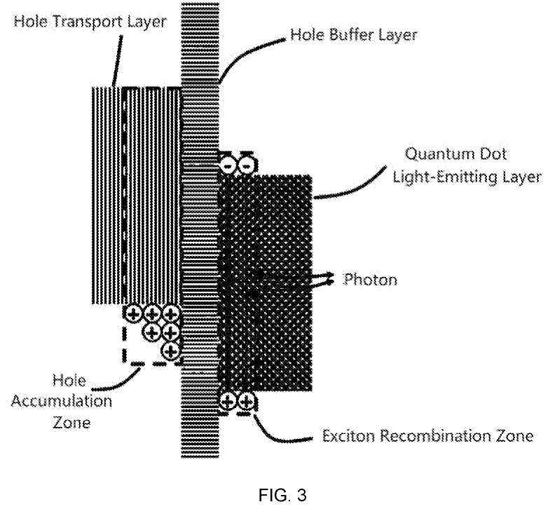

In a plurality of implementations, when the hole buffer layer is a single layer structure composed of the first hole buffer sub-layer, and the material of the first hole buffer sub-layer is the first hole buffer material, shown as FIG. 1, the quantum dot light-emitting diode comprises a substrate 101, an anode 102, a hole transport layer 103, a first hole buffer sub-layer 104, a quantum dot light-emitting layer 105, and a cathode 106, stacked sequentially from bottom up. The material of the first hole buffer sub-layer is the first hole buffer material. In the present embodiment, a single first hole buffer sub-layer is arranged between the hole transport layer and the quantum dot light-emitting layer, since the material of the first hole buffer sub-layer is a hole buffer material having an electrical conductivity less than 1×10⁻⁸ Sm⁻¹, which makes a part of the holes output from the anode be able to accumulate on the interface between the hole transport layer and the first hole buffer sub-layer, while another part of the holes will tunnel and pass through the first hole buffer sub-layer, before combining with a plurality of electrons in the quantum dot light-emitting layer and emitting light. Shown as FIG. 2 and FIG. 3, due to introducing the first hole buffer sub-layer, the present embodiment makes the holes originally all accumulated on the interface between the hole transport layer and the quantum dot light-emitting layer currently accumulate on the interface between the hole transport layer and the first hole buffer sub-layer, so as to separate the hole accumulation zone from the quantum dot exciton combination zone, which reduces an adverse effect of the spatial electric field to the exciton separation and the fluorescence quenching of the quantum dot, and improves the luminous efficiency, the stability and the service life of the QLED.

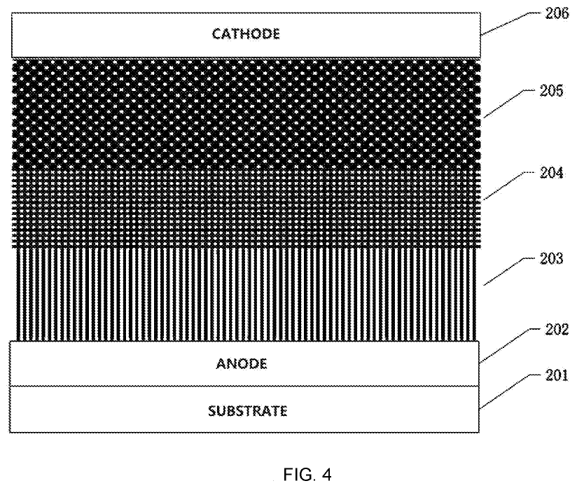

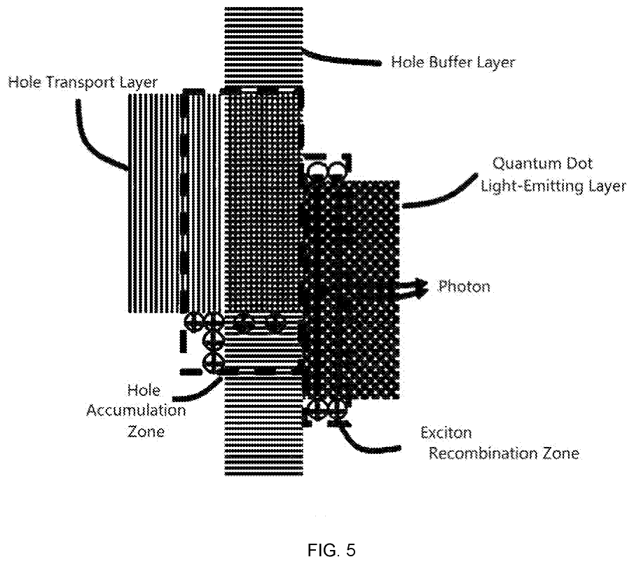

Since the electrical conductivity of the hole buffer material in the first hole buffer sub-layer is extremely low, if a thickness of the first hole buffer sub-layer is too large, a current of the QLED will decrease, and a driving voltage will increase, causing a performance of the QLED decrease; and if the thickness of the hole buffer sub-layer is too small, then a separation effect of the hole accumulation zone from the exciton recombination zone will be poor, which makes it impossible to reduce the adverse effect of the spatial electric field to the exciton separation and the fluorescence quenching of the quantum dot. Therefore, in order to optimize the performance of the QLED and improve the luminous efficiency thereof, in the present embodiment, a preferred thickness of the first hole buffer sub-layer is 1-3 nm. In a plurality of implementations, when the hole buffer layer is a single layer structure composed of the first hole buffer sub-layer, and the material of the first hole buffer sub-layer is a mixed material composed of a first hole buffer material and a fourth hole transport material, shown as FIG. 4, the quantum dot light-emitting diode comprises a substrate 201, an anode 202, a hole transport layer 203, a first hole buffer sub-layer 204, a quantum dot light-emitting layer 205, and a cathode 206, stacked sequentially from bottom up. The material of the first hole buffer sub-layer is the mixed material composed of the first hole buffer material and the fourth hole transport material. In the present embodiment, shown as FIG. 5, the first hole transport material in the first hole buffer sub-layer may act as a channel for holes transport, while the first hole buffer material acts as a barrier for holes transport, which may make the holes originally accumulated on the interface between the hole transport layer and the first hole buffer sub-layer get partially diffused in the first hole buffer sub-layer, thus achieving a purpose of widening the hole accumulation zone, and a widened hole accumulation zone may reduce a density of the charge accumulated in per unit volume of the hole transport layer, thus the electricity resistance of the hole transport layer is improved in an alternative way, which helps to improve a stability and a service life of the QLED; also a widened hole accumulation zone may further reduce the electric field strength near the interface of the quantum dot light-emitting layer, which is beneficial to reduce the exciton separation caused by the electric field and reduce the quantum dot fluorescence quenching, thereby helping to improve the luminous efficiency and the service life of the QLED.

In a plurality of implementations, in order to widen the hole accumulation zone, so as to improve the luminous efficiency of the QLED, a preferred thickness of the first hole buffer sub-layer is 1-7 nm.

In a plurality of implementations, the first hole buffer material is at least one of, but not limited to, Al₂O₃, SiO₂, AlN, Si₃N₄, and more. In some embodiments the first hole buffer material includes one component, such as one of Al₂O₃, SiO₂, AlN, and Si₃N₄, in some embodiments the first hole buffer material includes two components, such as two of Al₂O₃, SiO₂, AlN, and Si₃N₄, in some embodiments the first hole buffer material includes three components, such as three of Al₂O₃, SiO₂, AlN, and Si₃N₄. In a plurality of embodiments, the first hole transport material is at least one of, but not limited to, TAPC, NPB, NPD, TCTA, CBP, NiO, WO₃, MoO₃, V₂O₅ and more. In some embodiments the first hole transport material includes one component, such as one of TAPC, NPB, NPD, TCTA, CBP, NiO, WO₃, MoO₃, and V₂O₅, in some embodiments the first hole transport material includes two components, such as two of TAPC, NPB, NPD, TCTA, CBP, NiO, WO₃, MoO₃, and V₂O₅, in some embodiments the first hole transport material includes three components, such as three of TAPC, NPB, NPD, TCTA, CBP, NiO, WO₃, MoO₃, and V₂O₅. In a plurality of embodiments, the fourth hole transport material is at least one of, but not limited to, TAPC, NPB, NPD, TCTA, CBP, NiO, WO₃, MoO₃, V₂O₅ and more. In some embodiments the fourth hole transport material includes one component, such as one of TAPC, NPB, NPD, TCTA, CBP, NiO, WO₃, MoO₃, and V₂O₅, in some embodiments the fourth hole transport material includes two components, such as two of TAPC, NPB, NPD, TCTA, CBP, NiO, WO₃, MoO₃, and V₂O₅, in some embodiments the fourth hole transport material includes three components, such as three of TAPC, NPB, NPD, TCTA, CBP, NiO, WO₃, MoO₃, and V₂O₅.

In a plurality of implementations, the hole buffer layer may also be a stacked structure, comprising a first hole buffer sub-layer, a second hole buffer sub-layer, and a spacer layer arranged between the first hole buffer sub-layer and the second hole buffer sub-layer, a material of the spacer layer is a second hole transport material, a material of the second hole buffer sub-layer is a second hole buffer material or a mixed material composed of the second hole buffer material and a third hole transport material, wherein the electrical conductivity of the second hole buffer material is less than 1×10⁻⁸ Sm⁻¹.

In a plurality of implementations, the first hole buffer material is at least one of, but not limited to, Al₂O₃, SiO₂, AlN, Si₃N₄, and more. In some embodiments the first hole buffer material includes one component, such as one of Al₂O₃, SiO₂, AlN, and Si₃N₄, in some embodiments the first hole buffer material includes two components, such as two of Al₂O₃, SiO₂, AlN, and Si₃N₄, in some embodiments the first hole buffer material includes three components, such as three of Al₂O₃, SiO₂, AlN, and Si₃N₄. In a plurality of embodiments, the second hole buffer material is at least one of, but not limited to, Al₂O₃, SiO₂, AlN, Si₃N₄, and more. In some embodiments the second hole buffer material includes one component, such as one of Al₂O₃, SiO₂, AlN, and Si₃N₄, in some embodiments the second hole buffer material includes two components, such as two of Al₂O₃, SiO₂, AlN, and Si₃N₄, in some embodiments the second hole buffer material includes three components, such as three of Al₂O₃, SiO₂, AlN, and Si₃N₄. In a plurality of embodiments, the second hole transport material is at least one of, but not limited to, TAPC, NPB, NPD, TCTA, CBP, NiO, WO₃, MoO₃, V₂O₅ and more. In some embodiments the second hole transport material includes one component, such as one of TAPC, NPB, NPD, TCTA, CBP, NiO, WO₃, MoO₃, and V₂O₅, in some embodiments the second hole transport material includes two components, such as two of TAPC, NPB, NPD, TCTA, CBP, NiO, WO₃, MoO₃, and V₂O₅, in some embodiments the second hole transport material includes three components, such as three of TAPC, NPB, NPD, TCTA, CBP, NiO, WO₃, MoO₃, and V₂O₅. In a plurality of embodiments, the third hole transport material is at least one of, but not limited to, TAPC, NPB, NPD, TCTA, CBP, NiO, WO₃, MoO₃, V₂O₅ and more. In some embodiments the third hole transport material includes one component, such as one of TAPC, NPB, NPD, TCTA, CBP, NiO, WO₃, MoO₃, and V₂O₅, in some embodiments the third hole transport material includes two components, such as two of TAPC, NPB, NPD, TCTA, CBP, NiO, WO₃, MoO₃, and V₂O₅, in some embodiments the third hole transport material includes three components, such as three of TAPC, NPB, NPD, TCTA, CBP, NiO, WO₃, MoO₃, and V₂O₅.

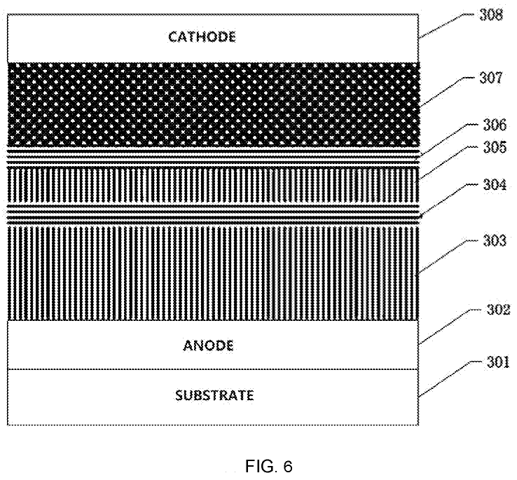

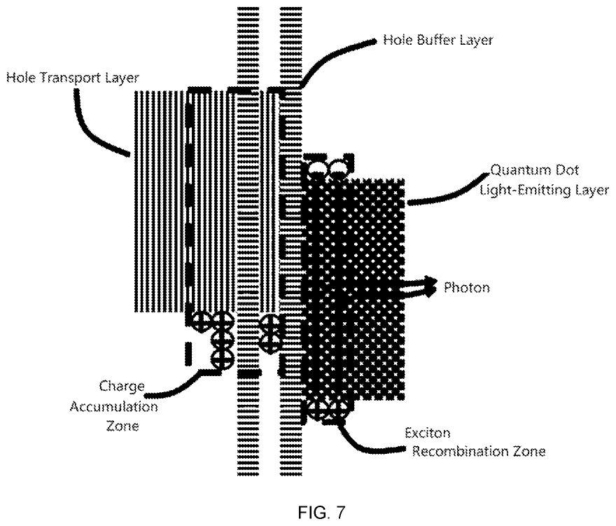

In a plurality of implementations, shown as FIG. 6, the quantum dot light-emitting diode comprises, stacked sequentially from bottom up, a substrate 301, an anode 302, a hole transport layer 303, a first hole buffer sub-layer 304, a spacer layer 305, a second hole buffer sub-layer 306, a quantum dot light-emitting layer 307, and a cathode 308. The material of the first hole buffer sub-layer is the first hole buffer material, and the material of the second hole buffer sub-layer is the second hole buffer material. Shown as FIG. 7, in the present embodiment, a part of the holes output from the anode tunnels and passes through the first hole buffer sub-layer and the second hole buffer sub-layer continuously, before moving to the quantum dot light-emitting layer and recombining with the electrons to emit light; while a remaining part of the holes get blocked by the first hole buffer sub-layer and the second hole buffer sub-layer arranged alternatively, before being accumulated at the interface between the hole transport layer and the first hole buffer sub-layer, and at the interface between the spacer layer and the second hole buffer sub-layer respectively. The present embodiment may not only achieve a purpose of widening an empty accumulation zone, but also separate the hole accumulation zone from the exciton recombination zone, which may not only reduce the adverse effect of the spatial electric field to the exciton separation and the fluorescence quenching of the quantum dot, but also reduce a density of the charge accumulated per unit volume of the hole transport layer, thereby improving the electricity resistance of the hole transport layer in an alternative way, thus helping to improve the luminous efficiency, the stability and the service life of the QLED. In order to In order to optimize the performance of the QLED and improve the luminous efficiency thereof, in the present embodiment, the thickness of the first hole buffer sub-layer is preferably 0.5-2 nm, and the thickness of the second hole buffer sub-layer is 0.5-2 nm.

In a plurality of implementations, a thickness of the spacer layer is 1-3 nm.

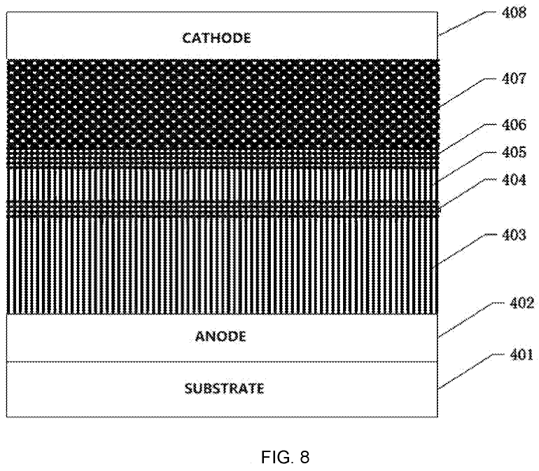

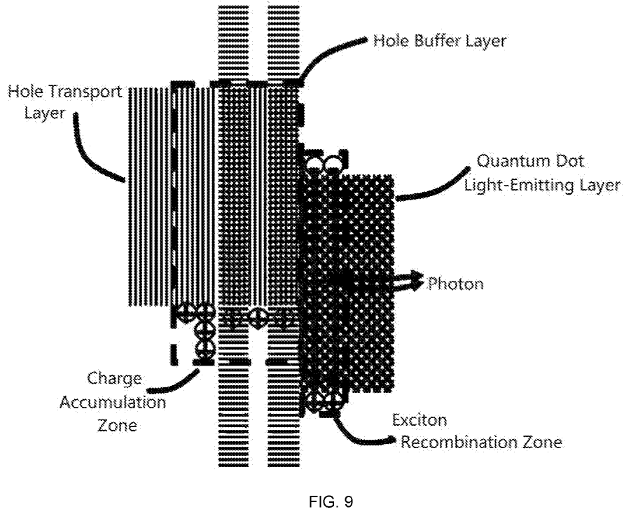

In a plurality of implementations, shown as FIG. 8, the quantum dot light-emitting diode comprises, stacked sequentially from bottom up, a substrate 401, an anode 402, a hole transport layer 403, a first hole buffer sub-layer 404, a spacer layer 405, a second hole buffer sub-layer 406, a quantum dot light-emitting layer 407, and a cathode 408. A material of the first hole buffer sub-layer is a mixed material composed of the first hole buffer material and the fourth hole transport material, a material of the second hole buffer sub-layer is a mixed material composed of the second hole buffer material and the third hole transport material. In the present embodiment, shown as FIG. 9, the hole transport material in the material of the first hole buffer sub-layer and the material of the second hole buffer sub-layer may act as a hole transport channel, the holes output from the anode may pass through the hole transport channels in the first hole buffer sub-layer and the second hole buffer sub-layer, before moving to the quantum dot light-emitting layer and recombining with the electrons to emit light; while another remaining part of the holes are distributed in the hole transport layer, the first hole buffer sub-layer, the spacer layer, and the second hole buffer sub-layer, so as to achieve the purpose of widening the hole accumulation zone, and further improve the luminous efficiency and the service life of the QLED.

In order to widen the hole accumulation zone of the QLED effectively, thus optimize the performance of the QLED and improve the luminous efficiency thereof, in the present embodiment, the thickness of the first hole buffer sub-layer is preferably 1-4 nm, and the thickness of the second hole buffer sub-layer is 1-4 nm.

In a plurality of implementations, a thickness of the spacer layer is 1-3 nm.

In a preferred implementation, a quantum dot light-emitting diode, wherein comprising, stacked sequentially from bottom up: a substrate, an anode, a hole transport layer, a first hole buffer sub-layer, a spacer layer, a second hole buffer sub-layer, a quantum dot light-emitting layer, and a cathode, the material of the first hole buffer sub-layer is the first hole buffer material, and the material of the second hole buffer sub-layer is a mixed material composed of the second hole buffer material and the third hole transport material. In the present embodiment, a part of the holes output from the anode tunnels and passes through the first hole buffer sub-layer, before passing through the second hole buffer sub-layer based on the third hole transport layer material, and moving to the quantum dot light-emitting layer, before recombining with the electrons to emit light; while a remaining part of the holes get blocked by the first hole buffer sub-layer, before being accumulated at the interface between the hole transport layer and the first hole buffer sub-layer, and at the interface between the spacer layer and the second hole buffer sub-layer respectively. The present embodiment may achieve a purpose of widening an empty accumulation zone, which is able to reduce an electric filed intensity close to the interface of the quantum dot light-emitting layer, beneficial to reduce the exciton separation caused by the electric field, and reduce the quantum dot fluorescence quenching, thus helpful to improve the luminous efficiency of the QLED; which may also reduce a density of the charges accumulated per unit volume in the hole transport layer, so as to improve the electricity resistance of the hole transport layer in an alternative way, which helps to improve the stability and service life of the QLED.

In a plurality of implementations, in order to optimize the performance of the QLED and improve the luminous efficiency thereof, the thickness of the first hole buffer sub-layer is 0.5-2 nm, the thickness of the second hole buffer sub-layer is 1-4 nm, and the thickness of the spacer layer is 1-3 nm.

In a plurality of implementations, a quantum dot light-emitting diode is further provided, wherein comprising, stacked sequentially from bottom up: a substrate, an anode, a hole transport layer, a first hole buffer sub-layer, a spacer layer, a second hole buffer sub-layer, a quantum dot light-emitting layer, and a cathode, the material of the first hole buffer sub-layer is a mixed material composed of the first hole buffer material and the fourth hole transport material, the material of the second hole buffer sub-layer is the second hole buffer material. In the present embodiment, a part of the holes output from the anode passes through the first hole buffer sub-layer based on the first hole transport layer material, before tunneling and passing through the second hole buffer sub-layer, and moving to the quantum dot light-emitting layer, before recombining with the electrons to emit light; while a remaining part of the holes get blocked by the second hole buffer sub-layer, before being accumulated at the interface between the hole transport layer and the first hole buffer sub-layer, the first hole buffer sub-layer, and the spacer layer respectively. The present embodiment may not only achieve a purpose of widening an empty accumulation zone, but also separate the hole accumulation zone from the exciton recombination zone, which may not only reduce the adverse effect of the spatial electric field to the exciton separation and the fluorescence quenching of the quantum dot, but also reduce a density of the charge accumulated per unit volume of the hole transport layer, thereby improving the electricity resistance of the hole transport layer in an alternative way, thus helping to improve the luminous efficiency, the stability and the service life of the QLED.

In a plurality of implementations, in order to optimize the performance of the QLED and improve the luminous efficiency thereof, the present embodiment prefers the thickness of the first hole buffer sub-layer to be 1-4 nm, the thickness of the second hole buffer sub-layer to be 0.5-2 nm, and the thickness of the spacer layer to be 1-3 nm.

In a plurality of implementations, the substrate may be a substrate made of a rigid material, including glass and more, or a substrate made of a flexible material, including one of PET or PI.

In a plurality of implementations, the anode may be selected from at least one of: indium-doped tin oxide (ITO), fluorine-doped tin oxide (FTO), antimony-doped tin oxide (ATO), aluminum-doped zinc oxide (AZO), and more. In some embodiments the anode includes one component, such as one of ITO, FTO, ATO, and AZO, in some embodiments the anode includes two components, such as two of ITO, FTO, ATO, AZO, in some embodiments the anode includes three components, such as three of ITO, FTO, ATO, and AZO.

In a plurality of implementations, a material of the hole transport layer may be selected from a plurality of materials having a good hole transport property, including but not limited to, at least one of TAPC, NPB, NPD, TCTA, CBP, NiO, WO₃, MoO₃, V₂O₅ and more. In some embodiments the material of the hole transport layer is one of TAPC, NPB, NPD, TCTA, CBP, NiO, WO₃, MoO₃, and V₂O₅, in some embodiments the material of the hole transport layer is two of TAPC, NPB, NPD, TCTA, CBP, NiO, WO₃, MoO₃, and V₂O₅, in some embodiments the material of the hole transport layer is three of TAPC, NPB, NPD, TCTA, CBP, NiO, WO₃, MoO₃, and V₂O₅.

In a plurality of implementations, the material of the quantum dot light-emitting layer is one of a compound semiconductor in a group of II-VI, a group of III-V, a group of or an elementary semiconductor in a group IV. In a plurality of embodiments, as an example, the compound semiconductors in the group of II-VI comprise at least one of: CdSe, ZnCdS, CdSeS, ZnCdSeS, CdSe/ZnS, CdSeS/ZnS, CdSe/CdS, CdSe/CdS/ZnS, ZnCdS/ZnS, CdS/ZnS, ZnCdSeS/ZnS. In some embodiments the compound semiconductors in the group of II-VI includes one component, such as one of CdSe, ZnCdS, CdSeS, ZnCdSeS, CdSe/ZnS, CdSeS/ZnS, CdSe/CdS, CdSe/CdS/ZnS, ZnCdS/ZnS, CdS/ZnS, and ZnCdSeS/ZnS, in some embodiments the compound semiconductors in the group of II-VI includes two components, such as two of CdSe, ZnCdS, CdSeS, ZnCdSeS, CdSe/ZnS, CdSeS/ZnS, CdSe/CdS, CdSe/CdS/ZnS, ZnCdS/ZnS, CdS/ZnS, and ZnCdSeS/ZnS, in some embodiments the compound semiconductors in the group of II-VI includes three components, such as three of CdSe, ZnCdS, CdSeS, ZnCdSeS, CdSe/ZnS, CdSeS/ZnS, CdSe/CdS, CdSe/CdS/ZnS, ZnCdS/ZnS, CdS/ZnS, and ZnCdSeS/ZnS. The compound semiconductors in the group of III-V comprise at least one of: GaAs, GaN, InP, InP/ZnS, and more. In some embodiments the compound semiconductors in the group of III-V includes one component, such as one of GaAs, GaN, InP, and InP/ZnS, in some embodiments the compound semiconductors in the group of III-V includes two components, such as two of GaAs, GaN, InP, and InP/ZnS, in some embodiments the compound semiconductors in the group of III-V includes three components, such as three of GaAs, GaN, InP, and InP/ZnS. The compound semiconductors in the group of I-III-VI comprise at least one of: CuInS, AgInS, CuInS/ZnS, AnInS/ZnS, and more. In some embodiments the compound semiconductors in the group of I-III-VI includes one component, such as one of CuInS, AgInS, CuInS/ZnS, and AnInS/ZnS, in some embodiments the compound semiconductors in the group of I-III-VI includes two components, such as two of CuInS, AgInS, CuInS/ZnS, and AnInS/ZnS, in some embodiments the compound semiconductors in the group of I-III-VI includes three components, such as three of CuInS, AgInS, CuInS/ZnS, and AnInS/ZnS. The elementary semiconductor in the group IV comprises at least one of: Si, C, graphene, and more. In some embodiments the elementary semiconductor in the group IV includes one component, such as one of Si, C, and graphene, in some embodiments the elementary semiconductor in the group IV includes two components, such as two of C, Si, and graphene, in some embodiments the elementary semiconductor in the group IV includes three components, such as three of C, Si, and graphene.

In a plurality of implementations, between the quantum dot light-emitting layer and the cathode, there is an electron transport layer further arranged, a material of the electron transport layer may be selected from a material owning a pretty good electrons transport performance, for example, including but not limited to, at least one of an n-type TPBi, Bepp2, BTPS, TmPyPb, ZnO, TiO₂, Fe₂O₃, SnO₂, Ta₂O₃, AlZnO, ZnSnO, InSnO and more. In some embodiments the material of the electron transport layer is one of n-type TPBi, Bepp2, BTPS, TmPyPb, ZnO, TiO₂, Fe₂O₃, SnO₂, Ta₂O₃, AlZnO, ZnSnO, and InSnO, in some embodiments the material of the electron transport layer is two of n-type TPBi, Bepp2, BTPS, TmPyPb, ZnO, TiO₂, Fe₂O₃, SnO₂, Ta₂O₃, AlZnO, ZnSnO, and InSnO, in some embodiments the material of the electron transport layer is three of n-type TPBi, Bepp2, BTPS, TmPyPb, ZnO, TiO₂, Fe₂O₃, SnO₂, Ta₂O₃, AlZnO, ZnSnO, and InSnO.

In a plurality of implementations, the cathode may be selected from one of an aluminum (Al) electrode, a silver (Ag) electrode, and a golden (Au) electrode.

It is noted that, the quantum dot light-emitting diode of the present disclosure may further comprise at least one of a plurality of following function layers: a hole injection layer arranged between the anode and the hole transport layer, and an electron injection layer arranged between the cathode and the electron transport layer. In some embodiments the quantum dot light-emitting diode of the present disclosure comprises a hole injection layer arranged between the anode and the hole transport layer, in some embodiments the quantum dot light-emitting diode of the present disclosure comprises an electron injection layer arranged between the cathode and the electron transport layer, in some embodiments the quantum dot light-emitting diode of the present disclosure comprises a hole injection layer arranged between the anode and the hole transport layer and an electron injection layer arranged between the cathode and the electron transport layer.

The present disclosure further provides a plurality of embodiments on a preparation method of the quantum dot light-emitting diode having a cis structure, further, comprising a plurality of following steps:

providing a substrate, forming an anode on the substrate;

preparing a hole transport layer on the anode;

preparing a first hole buffer sub-layer on the hole transport layer, a material of the first hole buffer sub-layer is a first hole buffer material, and an electrical conductivity of the first hole buffer material is less than 1×10⁻⁸ Sm⁻¹;

preparing a quantum dot light-emitting layer on the first hole buffer sub-layer;

preparing a cathode on the quantum dot light-emitting layer, and obtaining the quantum dot light-emitting diode.

In the present disclosure, a preparation method for each layer may be a chemical method or a physical method, wherein the chemical method comprises but not limited to, at least one of: a chemical vapor deposition method, a continuous ion layer adsorption and reaction method, an anodizing method, an electrolytic deposition method, and a co-precipitation method. In some embodiments the chemical method includes one method, such as one of chemical vapor deposition method, continuous ion layer adsorption and reaction method, anodizing method, electrolytic deposition method, and co-precipitation method, in some embodiments the chemical method includes two methods, such as two of chemical vapor deposition method, continuous ion layer adsorption and reaction method, anodizing method, electrolytic deposition method, and co-precipitation method, in some embodiments the chemical method includes three methods, such as three of chemical vapor deposition method, continuous ion layer adsorption and reaction method, anodizing method, electrolytic deposition method, and co-precipitation method. The physical method comprises but not limited to, at least one of: a solution methods (including a spin coating method, a printing method, a knife coating method, a dipping and pulling method, a dipping method, a spraying method, a roll coating method, a casting method, a slit coating method, a strip coating method, and more), an evaporation method (including a thermal evaporation method, an electron beam evaporation method, a magnetron sputtering method, a multi-arc ion coating method, and more), a deposition method (including a physical vapor deposition method, an atomic layer deposition method, a pulsed laser deposition method, and more), in some embodiments the physical method includes one method, such as one of solution method, evaporation method and deposition method, in some embodiments the physical method includes two methods, such as two of solution method, evaporation method an deposition method, in some embodiments the physical method includes three methods, such as three of solution method, evaporation method and deposition method.

In a plurality of implementations, a quantum dot light-emitting diode is further provided, which includes, stacked from bottom up: a substrate, an anode, a hole function layer, a quantum dot light-emitting layer, and a cathode, wherein the hole function layer comprises a hole transport layer and a hole buffer layer, the hole transport layer is arranged close to the anode, the hole buffer layer is arranged close to the quantum dot light-emitting layer, the hole buffer layer comprises a first hole buffer sub-layer arranged and affixed to the hole transport layer, and a material of the first hole buffer sub-layer is the first hole buffer material or a mixed material composed of the first hole buffer material and the fourth hole transport material, wherein a hole mobility of the first hole buffer material is less than 1×10⁻⁶ cm²V⁻¹s⁻¹.

The present embodiment arranges a hole function layer between the anode and the quantum dot light-emitting layer, the hole function layer comprises a hole transport layer and a hole buffer layer, by arranging the hole buffer layer, it may not only improve an electricity resistance of the hole transport layer, but also improve a luminous efficiency, a stability and a service life of the QLED. A mechanism for achieving a plurality of effects described above is as follows:

In the present embodiment, the material of the first hole buffer sub-layer is the first hole buffer material or the mixed material composed of the first hole buffer material and the fourth hole transport material, due to the hole mobility of the first hole buffer material is less than 1×10⁻⁶ cm²V⁻¹s⁻¹, which makes the first hole buffer sub-layer be able to play a role in delaying a movement of the holes to the quantum dot light-emitting layer, to reduce a cumulative density of the holes at the interface of the hole transport layer and the quantum dot light-emitting layer, and make a hole accumulation zone of the quantum dot light-emitting diode widen, thereby a plurality of following benefits are achieved: on one hand, a widened hole accumulation zone will reduce a requirement to the electricity resistance of the hole transport material, in other words, the widened hole accumulation zone will reduce the density of the charges accumulated in per unit volume of the hole transport layer, thereby improving the electricity resistance of the hole transport layer in an alternative way, which helps to improve the stability and the service life of the QLED; on another hand, a widened hole accumulation zone is able to reduce an electric field strength near the interface of the quantum dot light-emitting layer, which helps to reduce the exciton separation caused by the electric field and reduce the quantum dot fluorescence quenching, thereby helping to improve the luminous efficiency and the service life of the QLED.

In the present embodiment, a HOMO energy level of the first hole buffer material in the first hole buffer sub-layer is greater than a HOMO energy level of the hole transport layer material, and the HOMO energy level of the first hole buffer material is smaller than a VBM of the quantum dot in the quantum dot light-emitting layer. Since the HOMO energy level of the first hole buffer material is greater than the HOMO energy level of the hole transport layer material, there is a hole barrier existing at the interface between the hole transport layer and the first hole buffer sub-layer, making the holes accumulate at the interface, so as to achieve the purpose of widening the hole accumulation zone. Further, the HOMO energy level of the first hole buffer material matches the VBM of the quantum dot in the quantum dot light emitting layer better, which helps the holes in the first hole buffer sub-layer to jump into the quantum dot light-emitting layer and combine with the electrons to emit light, thereby improving the luminous efficiency of the QLED.

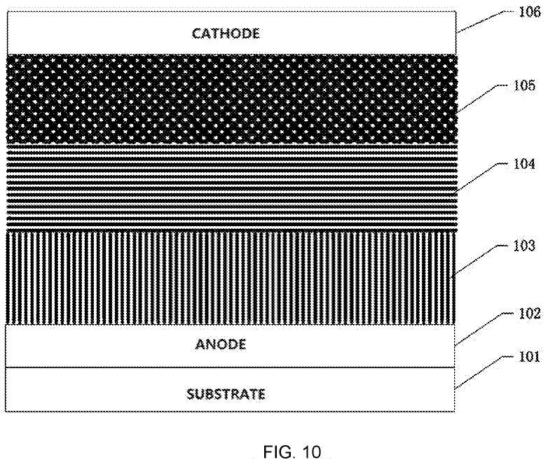

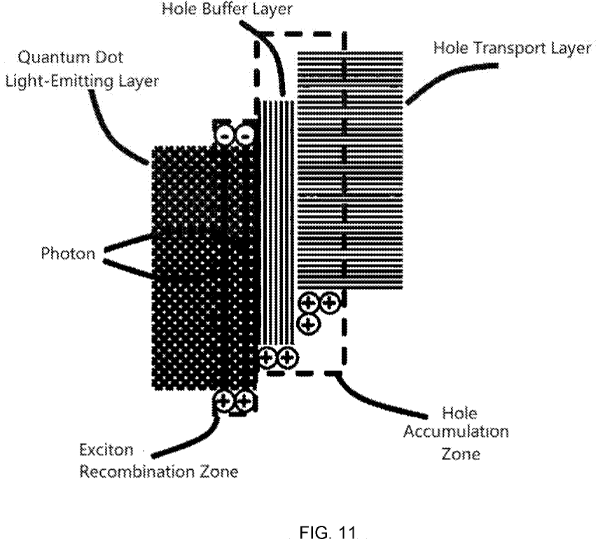

In a plurality of implementations, when the hole buffer layer is a single layer structure composed of the first hole buffer sub-layer, and the material of the first hole buffer sub-layer is the first hole buffer material, shown as FIG. 10, the quantum dot light-emitting diode comprises, stacked sequentially from bottom up, a substrate 101, an anode 102, a hole transport layer 103, a first hole buffer sub-layer 104, a quantum dot light-emitting layer 105, and a cathode 106, the material of the first hole buffer sub-layer is the first hole buffer material. In the present embodiment, shown as FIG. 11, a separate first hole buffer sub-layer is arranged between the hole transport layer and the quantum dot light-emitting layer, since there is a hole barrier at the interface between the hole transport layer and the first hole buffer sub-layer, which makes a part of the holes output from the anode accumulate at the interface, while a remaining part of the holes passes through the interface to the first hole buffer sub-layer; however, since the material of the first hole buffer sub-layer is the first hole buffer material having the hole mobility less than 1×10⁻⁶ cm²V⁻¹s⁻¹, that makes the holes moved into the first hole buffer sub-layer, wherein a part thereof gets delayed in the first hole buffer sub-layer, and another part thereof jumps from the first hole buffer sub-layer into the quantum dot light-emitting layer before combining with the electrons and emitting light. Due to introducing the first hole buffer sub-layer, the present embodiment makes the hole accumulation zone in the quantum dot light-emitting diode get widened, and the density of the spatial electric field get eliminated, an adverse effect of a spatial electric field to the exciton separation and the fluorescence quenching of the quantum dot get lowered, which has improved the luminous efficiency, the stability and the service life of the QLED.

In present embodiment, although a design of the first hole buffer sub-layer is able to play a role in widening the hole accumulation zone, an ability thereof to delay a hole transport is not conducive for a hole injecting into the quantum dot light-emitting layer, while injecting a sufficient amount of holes into the quantum dot light-emitting layer is a key to ensuring a luminous intensity and the luminous efficiency of the QLED. Based on this, a selection of the thickness of the first hole buffer sub-layer becomes a key to achieve a balance between two of them. In the present embodiment, the thickness of the first hole buffer sub-layer is preferred to be 1-6 nm, and within such a thickness range, the first hole buffer sub-layer may not only widen the hole accumulation zone in the quantum dot light-emitting diode, but also ensure that a sufficient amount of holes are injected into the quantum dot light-emitting layer, thus the luminous intensity and the luminous efficiency of the QLED are improved.

In the present embodiment, the first hole buffer material is selected from, but not limited to, at least one of TPBi, Bphen, TmPyPb, BCP, and TAZ. In some embodiments the first hole buffer material is one of TPBi, Bphen, TmPyPb, BCP, and TAZ, in some embodiments the first hole buffer material is two of TPBi, Bphen, TmPyPb, BCP, and TAZ, in some embodiments the first hole buffer material is three of TPBi, Bphen, TmPyPb, BCP, and TAZ.

In a plurality of implementations, when the hole buffer layer is a single layer structure composed of the first hole buffer sub-layer, and the material of the first hole buffer sub-layer is a mixed material composed of the first hole buffer material and a fourth hole transport material, that is, as shown in FIG. 12, the quantum dot light-emitting diode comprises, stacked sequentially from bottom up, a substrate 201, an anode 202, a hole transport layer 203, a first hole buffer sub-layer 204, a quantum dot light-emitting layer 205 and a cathode 206, the material of the first hole buffer sub-layer is a mixed material composed of the first hole buffer material and the fourth hole transport material. In the present embodiment, the hole transport material in the first hole buffer sub-layer may act as a hole transport channel, and the hole buffer material is responsible for delaying the holes transport, which may achieve an effect of delaying the holes transport, and increase the thickness of the hole buffer layer, thereby the hole accumulation zone is further widened, that improves the luminous efficiency and the service life of the QLED.

In the present embodiment, the thickness of the first hole buffer sub-layer is 1-15 nm, within a range of the thickness, the first hole buffer sub-layer may further widen the hole accumulation zone and inject enough amount of holes into the quantum dot light-emitting layer, the luminous intensity and the luminous efficiency of the QLED is thereby ensured.

In the present embodiment, the first hole buffer material is selected from at least one of, but not limited to, TPBi, Bphen, TmPyPb, BCP and TAZ. In some embodiments the first hole buffer material includes one component, such as one of TPBi, Bphen, TmPyPb, BCP and TAZ, in some embodiments the first hole buffer material includes two components, such as two of TPBi, Bphen, TmPyPb, BCP and TAZ, in some embodiments the first hole buffer material includes three components, such as three of TPBi, Bphen, TmPyPb, BCP and TAZ. Preferably, the first hole transport material is at least one of, but not limited to, TAPC, NPB, NPD, TCTA, CBP, NiO, WO₃, MoO₃, V₂O₅ and more. In some embodiments the first hole transport material includes one component, such as one of TAPC, NPB, NPD, TCTA, CBP, NiO, WO₃, MoO₃, and V₂O₅, in some embodiments the first hole transport material includes two components, such as two of TAPC, NPB, NPD, TCTA, CBP, NiO, WO₃, MoO₃, and V₂O₅, in some embodiments the first hole transport material includes three components, such as three of TAPC, NPB, NPD, TCTA, CBP, NiO, WO₃, MoO₃, and V₂O₅.

In a plurality of implementations, the hole buffer layer may also be a stacked structure, comprising: a first hole buffer sub-layer, a second hole buffer sub-layer, and a spacer layer arranged between the first hole buffer sub-layer and the second hole buffer sub-layer, a material of the spacer layer is a second hole transport material, and the material of the second hole buffer sub-layer is a second hole buffer material or a mixed material composed of a second hole buffer material and a third hole transport material, wherein a hole mobility of the second hole buffer material is less than 1×10⁻⁶ cm²V⁻¹s⁻¹.

In a plurality of implementations, the first hole buffer material is selected from at least one of, but not limited to, TPBi, Bphen, TmPyPb, BCP, TAZ and more. In some embodiments the first hole buffer material includes one component, such as one of TPBi, Bphen, TmPyPb, BCP, and TAZ, in some embodiments the first hole buffer material includes two components, such as two of TPBi, Bphen, TmPyPb, BCP, and TAZ, in some embodiments the first hole buffer material includes three components, such as three of TPBi, Bphen, TmPyPb, BCP, and TAZ. In a plurality of implementations, the second hole buffer material is selected from at least one of, but not limited to, TPBi, Bphen, TmPyPb, BCP, TAZ and more. In some embodiments the second hole buffer material includes one component, such as one of TPBi, Bphen, TmPyPb, BCP, and TAZ, in some embodiments the second hole buffer material includes two components, such as two of TPBi, Bphen, TmPyPb, BCP, and TAZ, in some embodiments the second hole buffer material includes three components, such as three of TPBi, Bphen, TmPyPb, BCP, and TAZ. In a plurality of implementations, the second hole transport material is selected from at least one of, but not limited to, TAPC, NPB, NPD, TCTA, CBP, NiO, WO₃, MoO₃, V₂O₅ and more. In some embodiments the second hole transport material includes one component, such as one of TAPC, NPB, NPD, TCTA, CBP, NiO, WO₃, MoO₃, and V₂O₅, in some embodiments the second hole transport material includes two components, such as two of TAPC, NPB, NPD, TCTA, CBP, NiO, WO₃, MoO₃, and V₂O₅, in some embodiments the second hole transport material includes three components, such as three of TAPC, NPB, NPD, TCTA, CBP, NiO, WO₃, MoO₃, and V₂O₅. In a plurality of implementations, the third hole transport material is selected from at least one of, but not limited to, TAPC, NPB, NPD, TCTA, CBP, NiO, WO₃, MoO₃, V₂O₅ and more. In some embodiments the third hole transport material includes one component, such as one of TAPC, NPB, NPD, TCTA, CBP, NiO, WO₃, MoO₃, and V₂O₅, in some embodiments the third hole transport material includes two components, such as two of TAPC, NPB, NPD, TCTA, CBP, NiO, WO₃, MoO₃, and V₂O₅, in some embodiments the third hole transport material includes three components, such as three of TAPC, NPB, NPD, TCTA, CBP, NiO, WO₃, MoO₃, and V₂O₅.

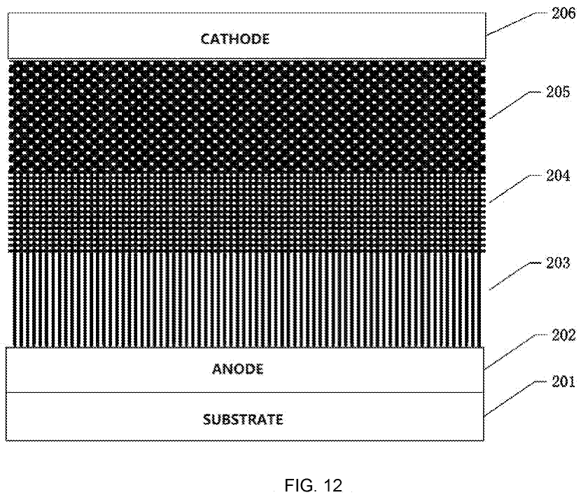

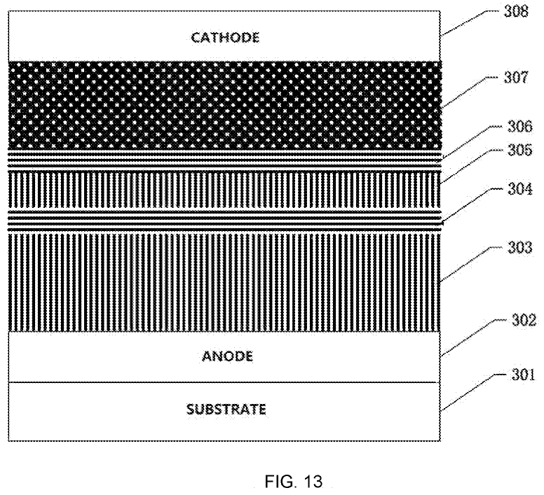

In a plurality of implementations, shown as FIG. 13, the quantum dot light-emitting diode comprises, stacked sequentially from bottom up, a substrate 301, an anode 302, a hole transport layer 303, a first hole buffer sub-layer 304, a spacer layer 305, a second hole buffer sub-layer 306, a quantum dot light-emitting layer 307, and a cathode 308, The material of the first hole buffer sub-layer is the first hole buffer material, and the material of the second hole buffer sub-layer is the second hole buffer material, wherein the hole mobility of both the first hole buffer material and the second hole buffer material is less than 1×10⁻⁶ cm²V⁻¹s⁻¹. In the present embodiment, the interface between the hole transport layer and the first hole buffer sub-layer has a hole barrier existing, and the interface between the spacer layer and the second hole buffer sub-layer has also a hole barrier existing, and both of the interfaces may accumulate holes, that is, the quantum dot light-emitting diode in the present embodiment has increased the interfaces for holes accumulation, further widened the holes accumulation zone, thus may improve the luminous efficiency and the service life of the QLED effectively.

In order to optimize the performance of the QLED and improve the luminous efficiency thereof, the thickness of the first hole buffer sub-layer is 0.5-3 nm, the thickness of the second hole buffer sub-layer is 0.5-3 nm.

In a plurality of implementations, the thickness of the spacer layer is 1-3 nm.

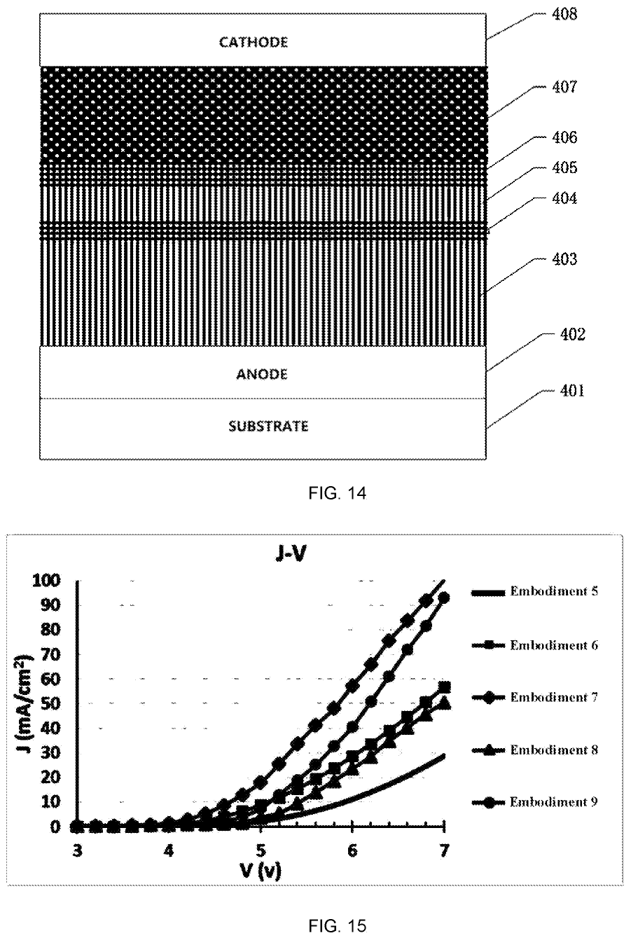

In a plurality of implementations, shown as FIG. 14, the quantum dot light-emitting diode comprises, stacked sequentially from bottom up, a substrate 401, an anode 402, a hole transport layer 403, a first hole buffer sub-layer 404, a spacer layer 405, a second hole buffer sub-layer 406, a quantum dot light-emitting layer 407, and a cathode 408. A material of the first hole buffer sub-layer is a mixed material composed of the first hole buffer material and the fourth hole transport material, a material of the second hole buffer sub-layer is a mixed material composed of the second hole buffer material and the third hole transport material, wherein the hole mobility of both the first hole buffer material and the second hole buffer material is less than 1×10⁻⁶ cm²V⁻¹s⁻¹. In the present embodiment, the first hole transport material in the first hole buffer sub-layer may act as a hole transport channel thereof, the third hole transport material in the second hole buffer sub-layer may act as a hole transport channel thereof, that is, the holes output from the anode may pass through the hole transport channels in the first hole buffer sub-layer and the second hole buffer sub-layer, before moving to the quantum dot light-emitting layer and recombining with the electrons to emit light; while another remaining part of the holes are distributed in the hole transport layer, the first hole buffer sub-layer, the spacer layer, and the second hole buffer sub-layer, so as to achieve the purpose of widening the hole accumulation zone, and further improve the luminous efficiency and the service life of the QLED.

In order to optimize the performance of the QLED and improve the luminous efficiency thereof, the present embodiment prefers the thickness of the first hole buffer sub-layer to be 1-8 nm, and the thickness of the second hole buffer sub-layer to be 1-8 nm.

In a plurality of implementations, the thickness of the spacer layer is 1-5 nm.

In a plurality of implementations, a quantum dot light-emitting diode comprises, stacked sequentially from bottom up, a substrate, an anode, a hole transport layer, a first hole buffer sub-layer, a spacer layer, a second hole buffer sub-layer, a quantum dot light-emitting layer, and a cathode. A material of the first hole buffer sub-layer is the first hole buffer material, a material of the second hole buffer sub-layer is a mixed material composed of the second hole buffer material and the third hole transport material, wherein the hole mobility of both the first hole buffer material and the second hole buffer material is less than 1×10⁻⁶ cm²V⁻¹s⁻¹. In the present embodiment, the holes output from the anode, wherein a part accumulates on the interface between the hole transport layer and the first hole buffer sub-layer, a part accumulates on the first hole buffer layer, the spacer layer and the second hole buffer layer, the present embodiment may also achieve the target of widening the holes accumulation zone, may reduce an electric filed intensity close to the interface of the quantum dot light-emitting layer, beneficial to reduce the exciton separation caused by the electric field, and reduce the quantum dot fluorescence quenching, thus helpful to improve the luminous efficiency of the QLED; which may also reduce a density of the charges accumulated per unit volume in the hole transport layer, so as to improve the electricity resistance of the hole transport layer in an alternative way, which helps to improve the stability and service life of the QLED.

In order to optimize the performance of the QLED and improve the luminous efficiency thereof, the present embodiment prefers the thickness of the first hole buffer sub-layer to be 0.5-3 nm, and the thickness of the second hole buffer sub-layer to be 1-8 nm, the thickness of the spacer layer to be 1-3 nm.

In a plurality of implementations, a quantum dot light-emitting diode comprises, stacked sequentially from bottom up, a substrate, an anode, a hole transport layer, a first hole buffer sub-layer, a spacer layer, a second hole buffer sub-layer, a quantum dot light-emitting layer, and a cathode. A material of the first hole buffer sub-layer is a mixed material composed of the first hole buffer material and the fourth hole transport material, a material of the second hole buffer sub-layer is the second hole buffer material, wherein the hole mobility of both the first hole buffer material and the second hole buffer material is less than 1×10⁻⁶ cm²V⁻¹s⁻¹. In the present embodiment, the holes output from the anode may accumulate on the interface between the hole transport layer and the first hole buffer sub-layer, and on the first hole buffer layer, the spacer layer and the second hole buffer layer. The present embodiment may also achieve the target of widening the holes accumulation zone, may reduce an electric filed intensity close to the interface of the quantum dot light-emitting layer, beneficial to reduce the exciton separation caused by the electric field, and reduce the quantum dot fluorescence quenching, thus helpful to improve the luminous efficiency of the QLED; which may also reduce a density of the charges accumulated per unit volume in the hole transport layer, so as to improve the electricity resistance of the hole transport layer in an alternative way, which helps to improve the stability and service life of the QLED.

In a plurality of implementations, in order to optimize the performance of the QLED and improve the luminous efficiency thereof, the present embodiment prefers the thickness of the first hole buffer sub-layer to be 1-8 nm, and the thickness of the second hole buffer sub-layer to be 0.5-3 nm, the thickness of the spacer layer to be 1-3 nm.

In a plurality of implementations, as shown in FIG. 10, the present disclosure further provides a plurality of embodiments on a preparation method of the quantum dot light-emitting diode having a cis structure, further, comprising a plurality of following steps:

providing a substrate, forming an anode on the substrate;

preparing a hole transport layer on the anode;

preparing a first hole buffer sub-layer on the hole transport layer, a material of the first hole buffer sub-layer is a first hole buffer material, and a hole mobility of the first hole buffer material is less than 1×10⁻⁶ cm²V⁻¹s⁻¹;

preparing a quantum dot light-emitting layer on the first hole buffer sub-layer;

preparing a cathode on the quantum dot light-emitting layer, and obtaining the quantum dot light-emitting diode.

In the present embodiment, a preparation method for each layer may be a chemical method or a physical method, wherein the chemical method comprises but not limited to, at least one of: a chemical vapor deposition method, a continuous ion layer adsorption and reaction method, an anodizing method, an electrolytic deposition method, and a co-precipitation method. In some embodiments the chemical method includes one method, such as one of chemical vapor deposition method, continuous ion layer adsorption and reaction method, anodizing method, electrolytic deposition method, and co-precipitation method, in some embodiments the chemical method includes two methods, such as two of chemical vapor deposition method, continuous ion layer adsorption and reaction method, anodizing method, electrolytic deposition method, and co-precipitation method, in some embodiments the chemical method includes three methods, such as three of chemical vapor deposition method, continuous ion layer adsorption and reaction method, anodizing method, electrolytic deposition method, and co-precipitation method. The physical method comprises but not limited to, at least one of: a solution methods (including a spin coating method, a printing method, a knife coating method, a dipping and pulling method, a dipping method, a spraying method, a roll coating method, a casting method, a slit coating method, a strip coating method, and more), an evaporation method (including a thermal evaporation method, an electron beam evaporation method, a magnetron sputtering method, a multi-arc ion coating method, and more), a deposition method (including a physical vapor deposition method, an atomic layer deposition method, a pulsed laser deposition method, and more) in some embodiments the physical method includes one method, such as one of solution method, evaporation method and deposition method, in some embodiments the physical method includes two methods, such as two of solution method, evaporation method an deposition method, in some embodiments the physical method includes three methods, such as three of solution method, evaporation method and deposition method.

Detailed descriptions are stated below by a plurality of embodiments.

### Embodiment 1

A quantum dot light-emitting diode, wherein comprising, stacked sequentially from bottom up, an ITO anode, an electron transport layer, a quantum dot light-emitting layer, a first hole buffer sub-layer, a hole transport layer, a hole injection layer and a cathode. A specific preparation method thereof comprises a plurality of steps below:

1, depositing a conductive thin film ITO on a transparent substrate to be a cathode, with a thickness of 50 nm;

2. depositing 40 nm ZnO as an electron transport layer on the cathode by a solution method, and annealing at 100° C. for 15 min in a N₂ environment;

3. depositing 25 nm CdSe/ZnS as a quantum dot light-emitting layer on the electron transport layer by a solution method, and annealing for 15 min at 100° C. in a N₂ environment;

4. transferring the transparent substrate to an atomic layer deposition system, before passing trimethyl aluminum and water vapor alternately on the quantum dot light-emitting layer, until 2 nm Al₂O₃ is deposited to be a first hole buffer sublayer;

5. transferring the transparent substrate to an evaporation chamber, evacuating to less than 1×10⁻⁴ pa, and vaporizing NPB at a rate of 0.1 nm/s on the first hole buffer sub-layer to be a hole transport layer, with a thickness of 30 nm;

6. vapor-depositing HAT-CN at a rate of 0.05 nm/s on the hole transport layer, to be a hole injection layer, with a thickness of 10 nm;

7. vapor-depositing Al on the hole injection layer at a rate of 0.4 nm/s, with a thickness of 100 nm.

### Embodiment 2

A quantum dot light-emitting diode, wherein comprising, stacked sequentially from bottom up, an ITO anode, a hole transport layer, a first hole buffer sub-layer, a quantum dot light-emitting layer, an electron transport layer, and a cathode. A specific preparation method thereof comprises a plurality of steps below:

1, depositing a conductive thin film ITO on a transparent substrate to be an anode, with a thickness of 50 nm;

2, adopting a RF power of 200 W, and ensuring an oxygen-to-argon ratio of 2:100, and sputtering 30 nm NiO on the anode at a rate of 0.02 nm/s, to be a hole transport layer;

3. adopting dual targets of Al₂O₃ and NiO, controlling an oxygen-to-argon ratio of 2:100, co-sputtering an Al₂O₃:NiO mixture on the hole transport layer at a rate of 0.01 nm/s, to be a first hole buffer sub-layer, with a thickness of 5 nm;

4, transferring the transparent substrate described above to a glove box, depositing 25 nm CdSe/ZnS on the first hole buffer sub-layer by a solution method, to be a quantum dot light-emitting layer, and annealing for 15 min at 100° C. in a N₂ environment;

5, depositing 40 nm ZnO on the quantum dot light-emitting layer by a solution method, to be an electron transport layer, and annealing for 15 min at 100° C. in a N₂ environment;

6, transferring the substrate described above to an evaporation chamber, evacuating to below 1×10⁻⁴ pa, and vapor-depositing Al on the electron transport layer at a rate of 0.4 nm/s, to be a cathode, with a thickness of 100 nm.

### Embodiment 3

A quantum dot light-emitting diode, wherein comprising, stacked sequentially from bottom up, an ITO anode, a hole transport layer, a first hole buffer sub-layer, a spacer layer, a second hole buffer sub-layer, a quantum dot light-emitting layer, an electron transport layer, and a cathode. A specific preparation method thereof comprises a plurality of steps below:

1, depositing a conductive thin film ITO on a transparent substrate to be an anode, with a thickness of 50 nm;

2, adopting a RF power of 200 W, and ensuring an oxygen-to-argon ratio of 2:100, and sputtering 30 nm NiO on the anode at a rate of 0.02 nm/s, to be a hole transport layer;

3, sputtering 1 nm Al₂O₃ on the hole transport layer at a rate of 0.01 nm/s, to be a first hole buffer sub-layer;

4, sputtering 2 nm NiO on the first hole buffer sub-layer at a rate of 0.01 nm/s, to be a spacer layer;

5, sputtering 1 nm Al₂O₃ on the spacer layer at a rate of 0.01 nm/s, to be a second hole buffer sub-layer;

6, transferring the substrate described above to a glove box, depositing 25 nm CdSe/ZnS on the second hole buffer sub-layer by a solution method, to be a quantum dot light-emitting layer, and annealing for 15 min at 100° C. in a N₂ environment;

7, depositing 40 nm ZnO on the quantum dot light-emitting layer by a solution method, to be an electron transport layer, and annealing for 15 min at 100° C. in a N₂ environment;

8, transferring the transparent substrate described above to an evaporation chamber, evacuating to below 1×10⁻⁴ pa, and vapor-depositing Al on the electron transport layer at a rate of 0.4 nm/s, to be a cathode, with a thickness of 100 nm;

### Embodiment 4

A quantum dot light-emitting diode, wherein comprising, stacked sequentially from bottom up, an ITO anode, a hole transport layer, a first hole buffer sub-layer, a spacer layer, a second hole buffer sub-layer, a quantum dot light-emitting layer, an electron transport layer, and a cathode. A specific preparation method thereof comprises a plurality of steps below:

1, depositing a conductive thin film ITO on a transparent substrate to be an anode, with a thickness of 50 nm;

2, adopting a RF power of 200 W, and ensuring an oxygen-to-argon ratio of 2:100, and sputtering 30 nm NiO on the anode at a rate of 0.02 nm/s, to be a hole transport layer;

3. adopting dual targets of Al₂O₃ and NiO, controlling an oxygen-to-argon ratio of 2:100, co-sputtering an Al₂O₃:NiO mixture on the hole transport layer at a rate of 0.01 nm/s, to be a first hole buffer sub-layer, with a thickness of 2 nm;

4, sputtering 3 nm NiO on the first hole buffer sub-layer at a rate of 0.01 nm/s, to be a spacer layer;

5, adopting dual targets of Al₂O₃ and NiO, controlling an oxygen-to-argon ratio of 2:100, co-sputtering an Al₂O₃:NiO mixture on the spacer layer at a rate of 0.01 nm/s, to be a second hole buffer sub-layer, with a thickness of 2 nm;

6, transferring the substrate described above to a glove box, depositing 25 nm CdSe/ZnS on the second hole buffer sub-layer by a solution method, to be a quantum dot light-emitting layer, and annealing for 15 min at 100° C. in a N₂ environment;

7, depositing 40 nm ZnO on the quantum dot light-emitting layer by a solution method, to be an electron transport layer, and annealing for 15 min at 100° C. in a N₂ environment;

8, transferring the transparent substrate described above to an evaporation chamber, evacuating to below 1×10⁻⁴ pa, and vapor-depositing Al on the electron transport layer at a rate of 0.4 nm/s, to be a cathode, with a thickness of 100 nm;

### Embodiment 5

A quantum dot light-emitting diode, wherein comprising, stacked sequentially from bottom up, an ITO cathode, an electron transport layer, a quantum dot light-emitting layer, a hole transport layer, a hole injection layer and an anode. A specific preparation method thereof comprises a plurality of steps below:

1, depositing a conductive thin film ITO on a transparent substrate, to be a cathode with a thickness of 50 nm;

2. depositing 40 nm ZnO on the cathode by a solution method, to be an electron transport layer, and annealing at 100° C. for 15 min in a N₂ environment;

3, depositing 25 nm CdSe/ZnS on the electron transport layer by a solution method, to be a quantum dot light-emitting layer, and annealing for 15 min at 100° C. in a N₂ environment;

4, transferring the transparent substrate described above to an evaporation chamber, evacuating to below 1×10⁻⁴ pa, and vapor-depositing NPB on a quantum dot light-emitting layer at a rate of 0.1 nm/s, to be a hole transport layer, with a thickness of 30 nm;

5, vapor-depositing HAT-CN on the hole transport layer at a rate of 0.05 nm/s, to be a hole injection layer, with a thickness of 10 nm;

6, vapor-depositing Al on the hole injection layer at a rate of 0.4 nm/s, to be an anode, with a thickness of 100 nm.

### Embodiment 6

A quantum dot light-emitting diode, wherein comprising, stacked sequentially from bottom up, an ITO cathode, an electron transport layer, a quantum dot light-emitting layer, a first hole buffer sub-layer, a hole transport layer, a hole injection layer and an anode. A specific preparation method thereof comprises a plurality of steps below:

1, depositing a conductive thin film ITO on a transparent substrate, to be a cathode with a thickness of 50 nm;

2. depositing 40 nm ZnO on the cathode by a solution method, to be an electron transport layer, and annealing at 100° C. for 15 min in a N₂ environment;

3, depositing 25 nm CdSe/ZnS on the electron transport layer by a solution method, to be a quantum dot light-emitting layer, and annealing for 15 min at 100° C. in a N₂ environment;

4, transferring the transparent substrate described above to an evaporation chamber, evacuating to below 1×10⁻⁴ pa, and vapor-depositing TPBi on the quantum dot light-emitting layer at a rate of 0.02 nm/s, to be a first hole buffer sub-layer, with a thickness of 3 nm;

5, vapor-depositing NPB on the first hole buffer sub-layer at a rate of 0.1 nm/s, to be a hole transport layer, with a thickness of 30 nm;

6, vapor-depositing HAT-CN on the hole transport layer at a rate of 0.1 nm/s, to be a hole injection layer, with a thickness of 10 nm.

7, vapor-depositing Al on the hole injection layer at a rate of 0.4 nm/s, to be an anode, with a thickness of 100 nm.

### Embodiment 7

A quantum dot light-emitting diode, wherein comprising, stacked sequentially from bottom up, an ITO cathode, an electron transport layer, a quantum dot light-emitting layer, a first hole buffer sub-layer, a hole transport layer, a hole injection layer and an anode. A specific preparation method thereof comprises a plurality of steps below:

1, depositing a conductive thin film ITO on a transparent substrate, to be a cathode with a thickness of 50 nm;

2. depositing 40 nm ZnO on the cathode by a solution method, to be an electron transport layer, and annealing at 100° C. for 15 min in a N₂ environment;

3, depositing 25 nm CdSe/ZnS on the electron transport layer by a solution method, to be a quantum dot light-emitting layer, and annealing for 15 min at 100° C. in a N₂ environment;

4, transferring the transparent substrate described above to an evaporation chamber, evacuating to below 1×10⁻⁴ pa, and co-vapor-depositing TPBi:NPB on the quantum dot light-emitting layer at a rate of 0.02 nm/s, to be a first hole buffer sub-layer, with a thickness of 7 nm;

5, vapor-depositing NPB on the first hole buffer sub-layer at a rate of 0.1 nm/s, to be a hole transport layer, with a thickness of 30 nm;

6, vapor-depositing HAT-CN on the hole transport layer at a rate of 0.1 nm/s, to be a hole injection layer, with a thickness of 10 nm.

7, vapor-depositing Al on the hole injection layer at a rate of 0.4 nm/s, to be an anode, with a thickness of 100 nm.

### Embodiment 8

A quantum dot light-emitting diode, wherein comprising, stacked sequentially from bottom up, an ITO cathode, an electron transport layer, a quantum dot light-emitting layer, a first hole buffer sub-layer, a spacer layer, a second hole buffer sub-layer, a hole transport layer, a hole injection layer and an anode. A specific preparation method thereof comprises a plurality of steps below:

1, depositing a conductive thin film ITO on a transparent substrate, to be a cathode with a thickness of 50 nm;

2. depositing 40 nm ZnO on the cathode by a solution method, to be an electron transport layer, and annealing at 100° C. for 15 min in a N₂ environment;

3, depositing 25 nm CdSe/ZnS on the electron transport layer by a solution method, to be a quantum dot light-emitting layer, and annealing for 15 min at 100° C. in a N₂ environment;

4, transferring the transparent substrate described above to an evaporation chamber, evacuating to below 1×10⁻⁴ pa, and vapor-depositing TPBi on the quantum dot light-emitting layer at a rate of 0.01 nm/s, to be a first hole buffer sub-layer, with a thickness of 1.5 nm;

5, vapor-depositing NPB on the first hole buffer sub-layer at a rate of 0.01 nm/s, to be a spacer layer, with a thickness of 2 nm;

6, vapor-depositing TPBi on the spacer layer at a rate of 0.01 nm/s, to be a second hole buffer sub-layer, with a thickness of 1.5 nm;

7, vapor-depositing NPB on the second hole buffer sub-layer at a rate of 0.1 nm/s, to be a hole transport layer, with a thickness of 30 nm;

8, vapor-depositing HAT-CN on the hole transport layer at a rate of 0.1 nm/s, to be a hole injection layer, with a thickness of 10 nm.

9, vapor-depositing Al on the hole injection layer at a rate of 0.4 nm/s, to be an anode, with a thickness of 100 nm.

### Embodiment 9

A quantum dot light-emitting diode, wherein comprising, stacked sequentially from bottom up, an ITO cathode, an electron transport layer, a quantum dot light-emitting layer, a first hole buffer sub-layer, a spacer layer, a second hole buffer sub-layer, a hole transport layer, a hole injection layer and an anode. A specific preparation method thereof comprises a plurality of steps below:

1, depositing a conductive thin film ITO on a transparent substrate, to be a cathode with a thickness of 50 nm;

2. depositing 40 nm ZnO on the cathode by a solution method, to be an electron transport layer, and annealing at 100° C. for 15 min in a N₂ environment;

3, depositing 25 nm CdSe/ZnS on the electron transport layer by a solution method, to be a quantum dot light-emitting layer, and annealing for 15 min at 100° C. in a N₂ environment;

4, transferring the transparent substrate described above to an evaporation chamber, evacuating to below 1×10⁻⁴ pa, and co-vapor-depositing TPBi:NPB on the quantum dot light-emitting layer at a rate of 0.02 nm/s, to be a first hole buffer sub-layer, with a thickness of 3 nm;

5, vapor-depositing NPB on the first hole buffer sub-layer at a rate of 0.02 nm/s, to be a spacer layer, with a thickness of 3 nm;

6, vapor-depositing TPBi:NPB on the spacer layer at a rate of 0.02 nm/s, to be a second hole buffer sub-layer, with a thickness of 3 nm;

7, vapor-depositing NPB on the second hole buffer sub-layer at a rate of 0.1 nm/s, to be a hole transport layer, with a thickness of 30 nm;

8, vapor-depositing HAT-CN on the hole transport layer at a rate of 0.1 nm/s, to be a hole injection layer, with a thickness of 10 nm.

9, vapor-depositing Al on the hole injection layer at a rate of 0.4 nm/s, to be an anode, with a thickness of 100 nm.

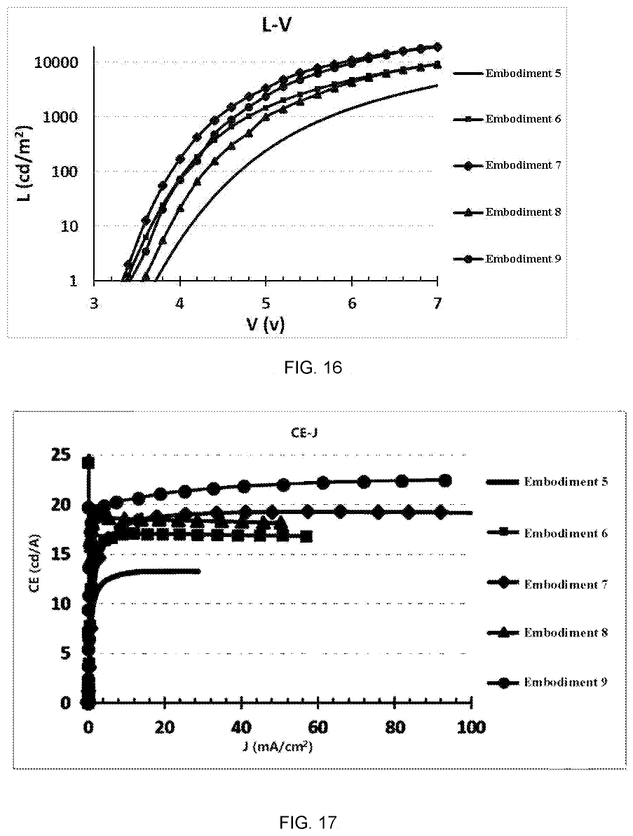

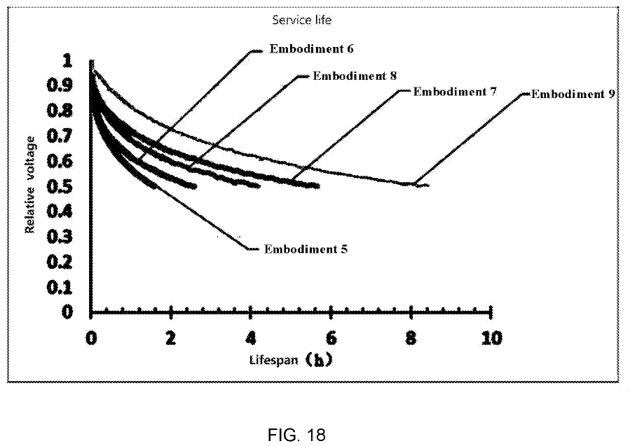

Further, the present disclosure also made a plurality of tests on a performance of the quantum dot light-emitting diodes in the embodiment 5 to embodiment 9 described above, a plurality of test results are shown in FIG. 15 to FIG. 18, wherein FIG. 15 illustrates a current density-voltage (J-V) curve of a QLED provided in the embodiments 5-9; FIG. 16 illustrates a luminance-voltage (L-V) curve of a QLED provided in the embodiments 5-9; FIG. 17 illustrates a current efficiency-current density (CE-J) curve of a QLED provided in the embodiments 5-9; FIG. 18 illustrates a lifespan curve of a QLED provided in the embodiments 5-9, wherein the QLED in the embodiment 5 is a reference device.

Shown as FIG. 15, the currents of the QLEDs in the embodiments 6-9 are all greater than the current of the reference device in the embodiment 5, that is due to the HOMO energy level of the hole buffer layer material is between the HOMO energy level of the hole transport layer material and the VBM of the quantum dots, which is more conducive to a transition of the holes from the hole buffer layer to the quantum dots.

Due to introducing the hole buffer layer, the hole accumulation zone is widened and the density of the spatial electric field is reduced, so an adverse effect of the spatial electric field to the quantum dot excitons is reduced. Thus both the brightness and the efficiency of the QLED with the hole buffer layer introduced are improved compared to the brightness and the efficiency of the reference device, as shown in FIG. 16 and FIG. 17. Wherein, the maximum current efficiency of the QLED shown in the embodiment 6 is 28.6% higher than that of the reference device in the embodiment 5, and the maximum current efficiency of the QLED shown in the embodiment 7 is 45.1% higher than that of the reference device in the embodiment 5. The maximum current efficiency of the QLED shown in the embodiment 8 is 42.1% higher than that of the reference device in the embodiment 5, and the maximum current efficiency of the QLED shown in the embodiment 9 is 69.2% higher than that of the reference device in the embodiment 5.

It can be seen from the FIG. 18, after introducing the hole buffer layer, the service life of QLEDs has all been improved to a varying degree. Wherein a T₅₀ of the QLED shown in the embodiment 6 is 63.3% higher than that of the reference device in the embodiment 5, the T₅₀ of the QLED shown in the embodiment 7 is 258% higher than that of the reference device in the embodiment 5, the T₅₀ of the QLED shown in the embodiment 8 is 163% higher than that of the reference device in the embodiment 5, the T₅₀ of the QLED shown in the embodiment 9 is 432% higher than that of the reference device in the embodiment 5.

All above, the hole function layer in the quantum dot light-emitting diode of the present disclosure comprises a hole transport layer and a hole buffer layer, the hole buffer layer comprises a first hole buffer sub-layer arranged and affixed to the hole transport layer, a material of the first hole buffer sub-layer is the first hole buffer material or a mixed material composed of the first hole buffer material and the first hole transport material; when the electrical conductivity of the first hole buffer material is less than 1×10⁻⁸ Sm⁻¹, the hole buffer layer may block the holes from transporting to the quantum dot light-emitting layer, making a part of the holes distribute on the interface between the hole transport layer and the hole buffer layer, so as to reduce an accumulation density of the holes on the interface between the hole transport layer and the quantum dot light-emitting layer, widen the hole accumulation zone, and separate the hole accumulation zone from the exciton recombination zone, reduce the fluorescence quenching of the quantum dots by the spatial electric field, which can improve not only the electricity resistance of the hole transport layer, but also the luminous efficiency, stability and service life of the QLED; when the hole mobility of the first hole buffer material is less than 1×10⁻⁶ cm²V⁻¹s⁻¹, the hole buffer layer may widen the hole accumulation zone, reduce a density of the holes accumulated in per unit volume of the hole transport layer, thus the electricity resistance of the hole transport layer is improved in an alternative way; a widened hole accumulation zone further reduces the spatial electric field near the exciton recombination zone, thus the exciton separation and fluorescence quenching of the quantum dot are reduced, thereby it may improve the luminous efficiency, stability and the service life of the QLED.

It should be understood that, the application of the present disclosure is not limited to the above examples listed. Ordinary technical personnel in this field can improve or change the applications according to the above descriptions, all of these improvements and transforms should belong to the scope of protection in the appended claims of the present disclosure.

1. A quantum dot light-emitting diode comprising, arranged in a stack: an anode, a cathode, a quantum dot light-emitting layer arranged between the anode and the cathode, and a hole function layer arranged between the anode and the quantum dot light-emitting layer; the hole function layer comprises a hole transport layer and a hole buffer layer, the hole transport layer is arranged close to the anode, the hole buffer layer is arranged close to the quantum dot light-emitting layer, wherein the hole buffer layer comprises a first hole buffer sub-layer arranged and affixed to the hole transport layer, and a material of the first hole buffer sub-layer is a first hole buffer material or a mixed material composed of a first hole buffer material and a fourth hole transport material, wherein an electrical conductivity of the first hole buffer material is less than 1×10⁻⁸ Sm⁻¹.

2. The quantum dot light-emitting diode according to claim 1, wherein the first hole buffer material is at least one of Al₂O₃, SiO₂, AlN, and Si₃N₄,

3. The quantum dot light-emitting diode according to claim 1, wherein the hole buffer layer is a single layer structure composed of the first hole buffer sub-layer, when a material of the first hole buffer sub-layer is a first hole buffer material, a thickness of the first hole buffer sub-layer is 1-3 nm.

4. The quantum dot light-emitting diode according to claim 1, wherein the hole buffer layer is a single layer structure composed of the first hole buffer sub-layer, when a material of the first hole buffer sub-layer is a mixed material composed of a first hole buffer material and a fourth hole transport material, a thickness of the first hole buffer sub-layer is 1-7 nm.

5. The quantum dot light-emitting diode according to claim 1, wherein the hole buffer layer is a stacked structure, comprising a first hole buffer sub-layer, a second hole buffer sub-layer, and a spacer layer arranged between the first hole buffer sub-layer and the second hole buffer sub-layer, a material of the spacer layer is a second hole transport material, a material of the second hole buffer sub-layer is a second hole buffer material or a mixed material composed of a second hole buffer material and a third hole transport material, wherein the electrical conductivity of the second hole buffer material is less than 1×10⁻⁸ Sm⁻¹.

6. The quantum dot light-emitting diode according to claim 5, wherein when the material of the first hole buffer sub-layer is the first hole buffer material, and the material of the second hole buffer sub-layer is the second hole buffer material, a thickness of the first hole buffer sub-layer is 0.5-2 nm, and a thickness of the second hole buffer sub-layer is 0.5-2 nm.

7. The quantum dot light-emitting diode according to claim 5, wherein when a material of the first hole buffer sub-layer is a mixed material composed of the first hole buffer material and the fourth hole transport material, a material of the second hole buffer sub-layer is a mixed material composed of the second hole buffer material and the third hole transport material, a thickness of the first hole buffer sub-layer is 1-4 nm, and a thickness of the second hole buffer sub-layer is 1-4 nm.

8. The quantum dot light-emitting diode according to claim 5, wherein when a material of the first hole buffer sub-layer is the first hole buffer material, and a material of the second hole buffer sub-layer is a mixed material composed of the second hole buffer material and the third hole transport material, a thickness of the first hole buffer sub-layer is 0.5-2 nm, a thickness of the second hole buffer sub-layer is 1-4 nm

9. The quantum dot light-emitting diode according to claim 5, wherein when a material of the first hole buffer sub-layer is a mixed material composed of the first hole buffer material and the fourth hole transport material, a material of the second hole buffer sub-layer is the second hole buffer material, a thickness of the first hole buffer sub-layer is 1-4 nm, a thickness of the second hole buffer sub-layer is 0.5-2 nm.

10. The quantum dot light-emitting diode according to claim 6, wherein the spacer layer has a thickness of 1-3 nm.

11. A quantum dot light-emitting diode comprising, arranged in a stack: an anode, a cathode, a quantum dot light-emitting layer arranged between the anode and the cathode, and a hole function layer arranged between the anode and the quantum dot light-emitting layer; the hole function layer comprises a hole transport layer and a hole buffer layer, the hole transport layer is arranged close to the anode, the hole buffer layer is arranged close to the quantum dot light-emitting layer, wherein the hole buffer layer comprises a first hole buffer sub-layer arranged and affixed to the hole transport layer, and a material of the first hole buffer sub-layer is a first hole buffer material or a mixed material composed of a first hole buffer material and a fourth hole transport material, wherein a hole mobility of the first hole buffer material is less than 1×10⁻⁶ cm²V⁻¹s⁻¹.

12. The quantum dot light-emitting diode according to claim 11, wherein the first hole buffer material comprises at least one of TPBi, Bphen, TmPyPb, BCP, and TAZ.

13. The quantum dot light-emitting diode according to claim 11, wherein the hole buffer layer is a single layer structure composed of the first hole buffer sub-layer, when a material of the first hole buffer sub-layer is a first hole buffer material, a thickness of the first hole buffer sub-layer is 1-6 nm.

14. The quantum dot light-emitting diode according to claim 11, wherein the hole buffer layer is a single layer structure composed of the first hole buffer sub-layer, when a material of the first hole buffer sub-layer is a mixed material composed of a first hole buffer material and a fourth hole transport material, a thickness of the first hole buffer sub-layer is 1-15 nm.

15. The quantum dot light-emitting diode according to claim 11, wherein the hole buffer layer is a stacked structure, comprising a first hole buffer sub-layer, a second hole buffer sub-layer, and a spacer layer arranged between the first hole buffer sub-layer and the second hole buffer sub-layer, a material of the spacer layer is a second hole transport material, a material of the second hole buffer sub-layer is a second hole buffer material or a mixed material composed of a second hole buffer material and a third hole transport material, wherein a hole mobility of the second hole buffer material is less than 1×10⁻⁶ cm²V⁻¹s⁻¹.

16. The quantum dot light-emitting diode according to claim 15, wherein when a material of the first hole buffer sub-layer is the first hole buffer material, and a material of the second hole buffer sub-layer is the second hole buffer material, a thickness of the first hole buffer sub-layer is 0.5-3 nm, a thickness of the second hole buffer sub-layer is 0.5-3 nm.

17. The quantum dot light-emitting diode according to claim 15, wherein when a material of the first hole buffer sub-layer is a mixed material composed of the first hole buffer material and the fourth hole transport material, a material of the second hole buffer sub-layer is a mixed material composed of the second hole buffer material and the third hole transport material, a thickness of the first hole buffer sub-layer is 1-8 nm, and a thickness of the second hole buffer sub-layer is 1-8 nm.

18. The quantum dot light-emitting diode according to claim 15, wherein when a material of the first hole buffer sub-layer is the first hole buffer material, and a material of the second hole buffer sub-layer is a mixture composed of the second hole buffer material and the third hole transport material, a thickness of the first hole buffer sub-layer is 0.5-3 nm, a thickness of the second hole buffer sub-layer is 1-8 nm.

19. The quantum dot light-emitting diode according to claim 15, wherein when a material of the first hole buffer sub-layer is a mixed material composed of the first hole buffer material and the fourth hole transport material, a material of the second hole buffer sub-layer is the second hole buffer material, a thickness of the first hole buffer sub-layer is 1-8 nm, and a thickness of the second hole buffer sub-layer is 0.5-3 nm.

20. The quantum dot light-emitting diode according to claim 16, wherein the second hole buffer material comprises at least one of: TPBi, Bphen, TmPyPb, BCP, and TAZ.
